(19) United States
(12) Patent Application Publication
(10) Pub. No.: US 2008/0199597 A1
(43) Pub. Date: Aug. 21, 2008

(54) Method For Producing A Three-Dimensional Circuit

(76) Inventor: Arved Huebler, Chemnitz (DE)

Correspondence Address: STITES & HARBISON PLLC, 1199 NORTH FAIRFAX STREET, SUITE 900, ALEXANDRIA, VA, 22314, US

(21) Appl. No.: 11/994,928

(22) PCT Filed: Jul. 11, 2006
(86) PCT No.: PCT/EP2006/006788

§ 371 Date: Jan. 7, 2008

(30) Foreign Application Priority Data
Jul. 15, 2005 (DE) 10 2005 033 218.8

(51) Int. Cl. H05K 3/00

(52) U.S. Cl. 427/97.1

(57) ABSTRACT

The invention relates to a method for producing a three-dimensional circuit having at least two superimposed, flexibly formed substrate layers comprising conductor paths and/or circuit elements composed of electrical functional materials. The method has a combination of the following method steps:
a. using a continuous sheet of material for the at least two substrate layers,
b. printing the electrical functional materials onto the substrate layers,
c. providing at least one folding or bending edge in the sheet of material in order to delimit the at least two substrate layers from each other, the folding operation being carried out inline with the printing operation,
d. folding the sheet of material about the folding or bending edge after the conductor paths and/or circuit elements have been printed on, so that the at least two substrate layers are arranged one above the other.

The invention relates to a method for producing a three-dimensional circuit having at least two superimposed substrate layers which comprise conductor paths and/or circuit elements.

DE-A-100 11 595 discloses a circuit arrangement in which a flexible printed circuit is connected to the circuit of a circuit carrier by means of a conductive adhesive. Compared with previously conventional solder connections, low production and assembly costs are obtained with this circuit arrangement.

DE-A-100 57 665 also describes an integrated circuit having at least two transistors which is in a stacked arrangement, for example a film being used as the substrate.

The object of the invention is further to reduce the production and assembly costs of a three-dimensional circuit. That object is achieved according to the invention by the features of claim 1.

The method according to the invention for producing a three-dimensional circuit having at least two superimposed, flexibly formed substrate layers comprising conductor paths and/or circuit elements composed of electrical functional materials is characterised by a combination of the following method steps:
a. using a continuous sheet of material for the at least two substrate layers (1, 2, 3),
b. printing the electrical functional materials onto the substrate layers (1, 2, 3),
c. providing at least one folding or bending edge (5) in the sheet of material in order to delimit the at least two substrate layers from each other, the folding operation being carried out inline with the printing operation,
d. folding the sheet of material about the folding or bending edge after the conductor paths and/or circuit elements have been printed on, so that the at least two substrate layers are arranged one above the other.

Polymer materials are preferably used as the functional materials and are printed onto the flexible substrate layers. As a result, production is especially simple and inexpensive.

Depending on the application, an electrically insulating layer may be arranged between the substrate layers and may be composed of a solid substrate, especially of the sheet of material from which the substrate layers are also manufactured, or alternatively of a substance which is applied in liquid or gaseous form.

Furthermore, the substrate layers can be brought into electrical contact with each other by means of electrical contact connections between the conductor paths and/or circuit elements.

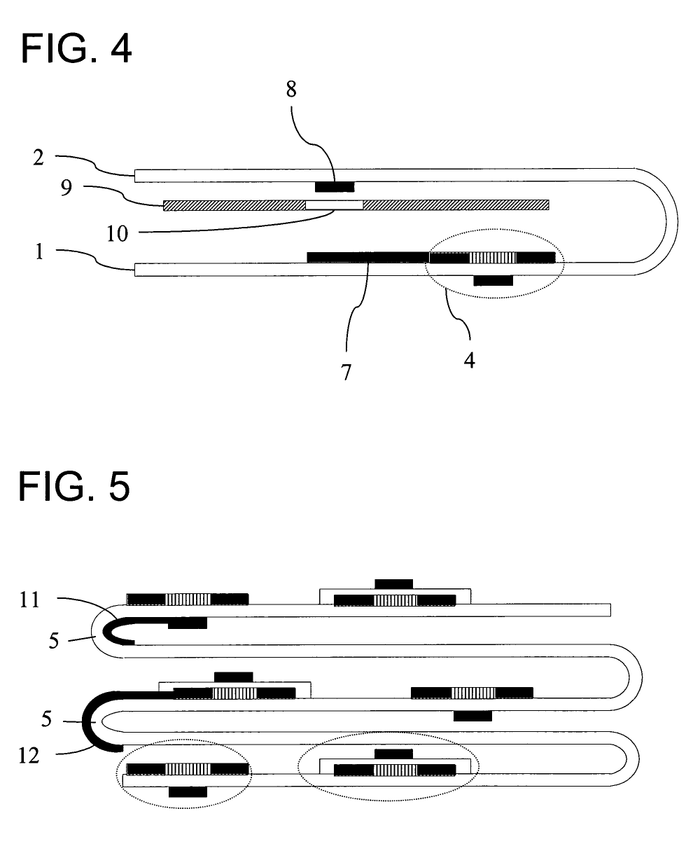

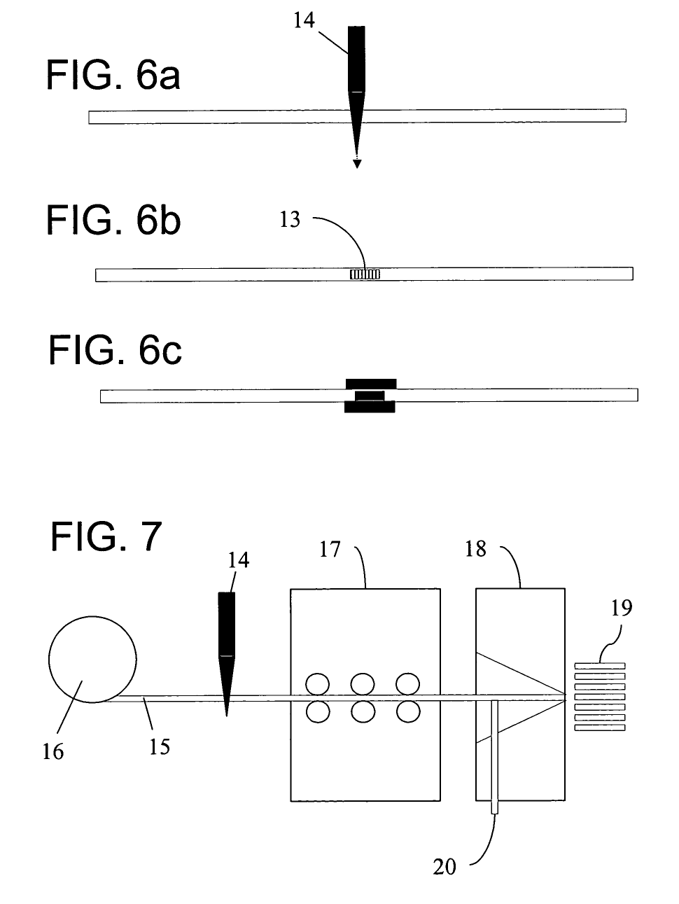

According to a further development of the invention, the production of electrical contact connections between the conductor paths and/or circuit elements can be effected by printing electrical functional materials. This can be effected in the case of two adjacent substrate layers by, for example, contacting directly opposing sites by a press contact, an opening being provided (for example by perforation) in an intermediate layer in the region of those two contact sites (see FIG. 4). Moreover, an electrically conductive connection can also be produced by means of the folding or bending edge (see FIG. 5). Finally, any necessary connection through a substrate layer can also be produced by providing, by means of a perforating device, a perforation in the substrate at the sites at which through-contacting is to take place (FIGS. 6a,b). A contact can be produced by subsequent, optionally multiple, overprinting of the perforation from both sides of the substrate layer.

Further advantages and developments of the invention are explained in more detail hereinafter by means of the description of some embodiments and the drawings.

In the drawings

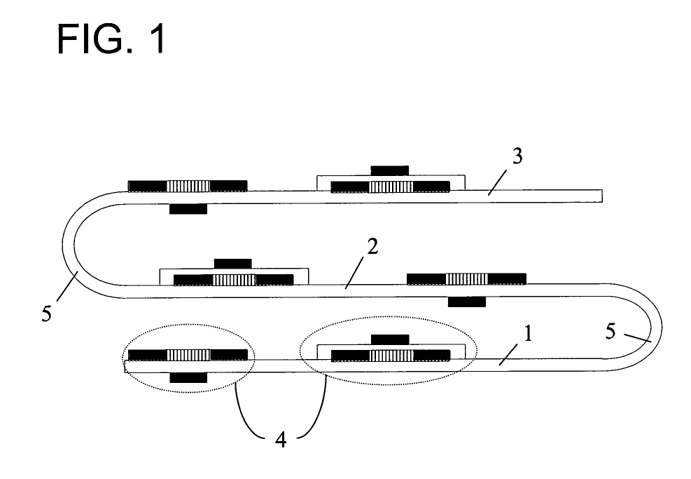

FIG. 1 shows a three-dimensional circuit having continuous substrate layers,

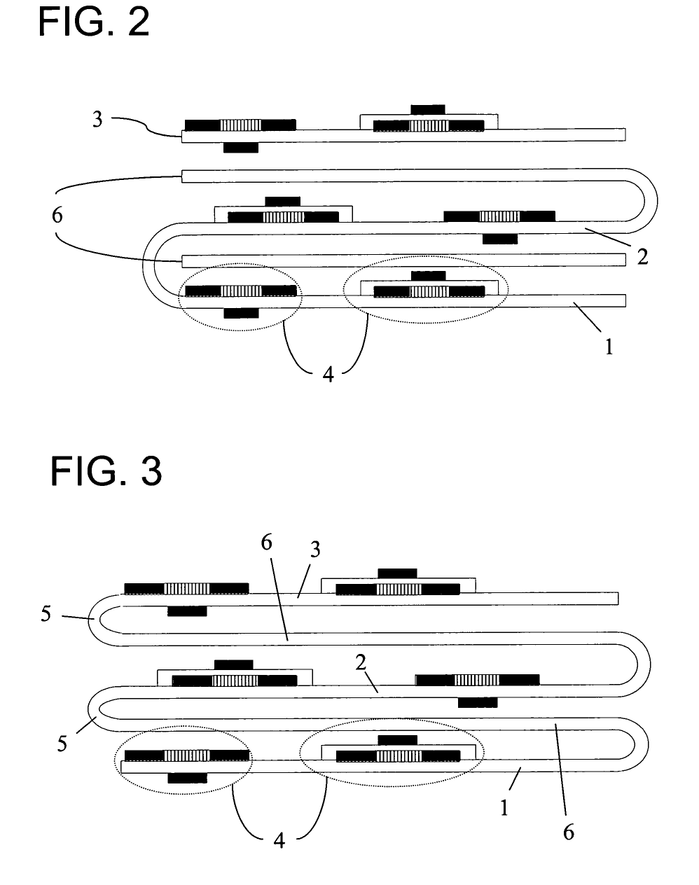

FIG. 2 shows a three-dimensional circuit having continuous substrate layers and separate insulating layers,

FIG. 3 shows a three-dimensional circuit in which the substrate layers and insulating layers are continuous,

FIG. 4 shows a three-dimensional circuit having continuous substrate layers with an insulating layer of adhesive,

FIG. 5 shows a three-dimensional circuit having an electrically conductive connection by means of the folding or bending edge,

FIGS. 6a-6c are a schematic representation of the production of a contact,

FIG. 7 is a schematic representation of the production process.

The three-dimensional circuit shown schematically in FIG. 1 comprises three superimposed substrate layers 1, 2, 3, the substrate layers comprising conductor paths and/or circuit elements 4. The conductor paths and/or circuit elements are printed from electronic functional materials, especially based on polymers, onto the flexibly formed substrate layers. It is possible to produce, for example, electrical and electronic components, such as transistors, diodes, resistors, capacitors, etc., which are connected in an integrated manner by conductor paths applied directly to the substrate. The individual substrate layers are composed, for example, of films.

The substrate layers are manufactured from a continuous sheet of material, the substrate layers being separated from each other by a folding or bending edge 5 in the sheet of material and, after the conductor paths and/or circuit elements 4 have been applied, the sheet of material is folded about the folding or bending edge in such a manner that the two substrate layers are arranged one above the other.

Production is especially inexpensive when the electrical functional materials are applied to the flexible substrate layers by printing processes. In particular, letterpress, rotogravure or planographic processes are used.

The individual substrate layers 1, 2, 3 are connected securely to each other, it being possible to produce the secure connection, for example, by means of an adhesive, a laminating step, a perforating operation, by partial melting of the substrate layers or in some other manner.

Use is preferably made of conventional printing technology and the folding processes known in that context, both for the application of the conductor paths and/or circuit elements and for the folding operation.

The folding process takes place inline with the operation of printing the electronic circuit elements. This type of folding has the advantage that the printed structures are exactly defined and fixed in their spatial association on the substrate with the printing operation and, after folding, can be laid accurately on each other. It is therefore possible to lay several hundred layers exactly on top of each other. In this context, the term “inline” means that continuous assembly-line production is involved here.

The conduction distance between two vertically linked electronic components, such as, for example, two superimposed transistors, is therefore very small and is defined substantially by the thickness of the substrate layers. The thickness lies typically in the range of from 10 to 100 μm and is therefore more favourable than when links can be produced only in one plane. Any known process, such as, for example, newspaper folding, knife folding or buckle folding, comes into consideration as a folding process and, in particular, both longitudinal and transverse folds may be provided for.

As a rule, an insulating layer, which may be constituted either by an additional substrate layer or film layer (see FIGS. 2 and 3) or by an additionally applied insulating layer of material (FIG. 4), is provided between the individual layers.

In the embodiment according to FIG. 2, the three substrate layers 1, 2, 3 are formed from a continuous sheet of material and the two electrically insulating layers 6 are in the form of individual separated layers, while in the embodiment according to FIG. 3, the substrate layers 1, 2, 3 and the electrically insulating layers 6 are manufactured from a continuous sheet of material, the individual layers being separated from each other by folding or bending edges 5.

The individual layers of the circuit must be connected to each other permanently, so that it is necessary to adhesively bond or paste each layer to the adjacent layer. This function can be combined with insulation, either a layer of film being introduced as the insulating paste film (reference sign 6 in FIGS. 2 and 3) or a layer of adhesive 9 having insulating properties being applied as the intermediate layer, as shown in FIG. 4.

A three-dimensional circuit is possible, however, only when the individual substrate layers contained in the circuit stack can be connected to each other electrically. This can be effected for two adjacent substrate layers, for example, by contacting directly opposing sites 7,8 by a press contact, an opening 10 being provided in the insulating adhesive layer 9 in the region of those two contact sites 7,8 (see FIG. 4).

In addition, an electrically conductive connection can also be produced by means of the folding or bending edge 5 (see FIG. 5). The conductive material 11, 12 applied must be sufficiently resilient to withstand the folding operation without rupture.

In order to produce the connection through a substrate layer, this being necessary for the circuit construction according to the invention, it is also possible, by means of a perforating device 14, to provide a perforation 13 in the substrate at the sites at which through-contacting is to take place (FIGS. 6a, b). A contact can be produced by subsequent, optionally multiple, overprinting of the perforation 13 from both sides of the substrate layer (FIG. 6c). The hole size of the perforation and also the surface tension of the functional materials applied to both sides are so adjusted to each other that optimum wetting of the hole cross-section can take place. It may be necessary to provide several perforations at a conductive junction in order to achieve sufficient conductivity. For example, mechanical perforating units may be used as perforating devices 14. Furthermore, the perforations can also be burnt into the substrate layer by means of a laser beam.

An embodiment of a production process according to the invention is shown in FIG. 7. In the first step, the sheet of material 15 is unwound from a storage roller 16 and first of all perforated by means of a perforating device 14. Subsequently, the substrate web can be printed on one or both sides in a printing unit 17, it being possible for any necessary drying processes also to take place here. In addition, a structured insulating layer of adhesive is also applied there insofar as the intermediate layer is not formed by part of the sheet of material or separate layers. One or more folding processes then take place in a folding unit 18 so that ultimately a suitable three-dimensional circuit 19 is formed. The cutting operation for separating the three-dimensional circuits therefore does not take place until after the folding process, so that the folding process takes place inline with the printing process.

Expediently, the individual substrate layers are adhesively bonded to each other, the adhesive being applied in the printing process or during the folding process and optionally even taking on electrical functions, especially as an insulator, at the same time. Other substrate webs 20, for example provided with electronic functional components, may optionally also be introduced into the folding process so that the three-dimensional circuit 19 is formed from various webs placed together.

1. Method for producing a three-dimensional circuit having at least two superimposed, flexibly formed substrate layers comprising conductor paths and/or circuit elements composed of electrical functional materials, characterised by a combination of the following method steps:
a. using a continuous sheet of material for the at least two substrate layers,
b. printing the conductor paths and the circuit elements by means of the electrical functional materials onto the flexibly formed substrate layers,
c. providing at least one folding or bending edge in the sheet of material in order to delimit the at least two substrate layers from each other, the folding operation being carried out inline with the printing operation,
d. folding the sheet of material about the folding or bending edge after the conductor paths and/or circuit elements have been printed on, so that the at least two substrate layers are arranged one above the other.

2. Method according to claim 1, characterized in that an electrically insulating layer is arranged between the substrate layers.

3. Method according to claim 2, characterized in that a solid substrate, especially the sheet of material from which the substrate layers are also manufactured, is used for the electrically insulating layer.

4. Method according to claim 1, characterized in that an electrically insulating layer composed of a liquid or gaseous substance is applied between the substrate layers.

5. Method according to claim 1, characterized in that the substrate layers are brought into electrical contact with each other by means of electrical contact connections between the conductor paths and/or circuit elements.

6. Method according to claim 1, characterized in that the production of electrical contact connections between the conductor paths and/or circuit elements is effected by printing electrical functional materials.

7. Method according to claim 1, characterized in that in order to produce electrical contact connections between the conductor paths and/or circuit elements of various substrate layers, perforations are produced in one or more substrate layers.

8. Method according to claim 1, characterized in that the sheet of material is provided for a plurality of three-dimensional circuits.

9. Method according to claim 1, characterized in that the electrical functional materials are based on polymers.
